(19) United States
(12) Patent Application Publication
(10) Pub. No.: US 2011/0133159 A1
(43) Pub. Date: Jun. 9, 2011

(54) SEMICONDUCTOR LIGHT-EMITTING DEVICE WITH PASSIVATION IN P-TYPE LAYER

(75) Inventors: Fengyi Jiang, Jiangxi (CN); Yingwen Tang, Jiangxi (CN); Chunlan Mo, Jiangxi (CN); Li Wang, Jiangxi (CN)

(73) Assignee: LATTICE POWER (JIANGXI) CORPORATION, Nanchang, Jiang Xi (CN)

(21) Appl. No.: 13/059,400

(22) PCT Filed: Aug. 19, 2008
(86) PCT No.: PCT/CN08/01494

§ 371 Date: Feb. 16, 2011

(30) Foreign Application Priority Data
Aug. 19, 2008 (CN) PCT/CN2008/001494

(51) Int. Cl. H01L 33/06; H01L 33/44

(52) U.S. Cl. 257/13; 438/38; 257/E33.008; 257/E33.06

(57) ABSTRACT

A semiconductor light-emitting device includes a substrate, a first doped semiconductor layer, a second doped semiconductor layer situated above the first doped semiconductor layer, and a multi-quantum-well (MQW) active layer situated between the first and the second doped layers. The device also includes a first electrode coupled to the first doped semiconductor layer, wherein part of the first doped semiconductor layer is passivated, and wherein the passivated portion of the first doped semiconductor layer substantially insulates the first electrode from the edges of the first doped semiconductor layer, thereby reducing surface recombination. The device further includes a second electrode coupled to the second doped semiconductor layer and a passivation layer which substantially covers the sidewalls of the first and second doped semiconductor layers, the MQW active layer, and part of the horizontal surface of the second doped semiconductor layer which is not covered by the second electrode.

### BACKGROUND

1. Field

The present disclosure relates to a semiconductor light-emitting device. More specifically, the present invention relates to a novel semiconductor light-emitting device with passivation in the p-type layer that can effectively reduce the leakage current and enhance the device reliability.

2. Related Art

Solid-state lighting is expected to be the next wave of illumination technology. High-brightness light-emitting diodes (HB-LEDs) are emerging in an increasing number of applications, from serving as the light source for display devices to replacing light bulbs for conventional lighting. Typically, cost, efficiency, and brightness are the three foremost metrics for determining the commercial viability of LEDs.

An LED produces light from an active region which is “sandwiched” between a positively doped layer (p-type doped layer) and a negatively doped layer (n-type doped layer). When the LED is forward-biased, the carriers, which include holes from the p-type doped layer and electrons from the n-type doped layer, recombine in the active region. In direct band-gap materials, this recombination process releases energy in the form of photons, or light, whose wavelength corresponds to the band-gap energy of the material in the active region.

To ensure high efficiency of an LED, it is desirable to have the carriers recombine only in the active region instead of other places such as the lateral surface of the LED. However, due to the abrupt termination of the crystal structure at the lateral surface of the LED, there are large numbers of recombination centers on such surface. In addition, the surface of an LED is very sensitive to its surrounding environment, which may lead to added impurities and defects. Environmentally induced damage can severely degrade the reliability and stability of an LED. In order to insulate an LED from various environmental factors, such as humidity, ion impurity, external electrical field, heat, etc., and to maintain the functionality and stability of the LED, it is important to maintain the surface cleanness and to ensure reliable LED packaging. Moreover, it is also critical to protect the surface of an LED using surface passivation, which typically involves depositing a thin layer of non-reactive material on the surface of the LED.

FIG. 1 illustrates a traditional passivation method for an LED with a vertical-electrode configuration with, from the top down, a passivation layer 100, an n-side (or p-side) electrode 102, an n-type (or p-type) doped semiconductor layer 104, an active layer 106 based on a multi-quantum-well (MQW) structure, a p-type (or n-type) doped semiconductor layer 108, a p-side (or n-side) electrode 110, and a substrate 112.

The passivation layer blocks the undesirable carrier recombination at the LED surface. For the vertical-electrode LED structure shown in FIG. 1, surface recombination tends to occur on the sidewalls of the MQW active region 106. However, the sidewall coverage by a conventional passivation layer, for example, layer 100 shown in FIG. 1, is often less than ideal. The poor sidewall coverage is typically a result of standard thin-film deposition techniques, such as plasma-enhanced chemical vapor deposition (PECVD) and magnetron sputtering deposition. The quality of sidewall coverage by the passivation layer is worse in devices with steeper steps, e.g., steps higher than 2 μm, which is the case for most vertical-electrode LEDs. Under such conditions, the passivation layer often contains a large number of pores, which can severely degrade its ability to block the surface recombination of carriers. An increased surface recombination rate, in turn, increases the amount of the reverse leakage current, which results in reduced efficiency and stability of the LED. In addition, the metal that forms the p-side electrode can diffuse into the p-n junction, leading to increased leakage current.

### SUMMARY

One embodiment of the present invention provides a semiconductor light-emitting device. The device includes a substrate, a first doped semiconductor layer situated above the substrate; a second doped semiconductor layer situated above the first doped semiconductor layer, and a multi-quantum-well (MQW) active layer situated between the first and the second doped semiconductor layers. The device also includes a first electrode coupled to the first doped semiconductor layer, wherein part of the first doped semiconductor layer is passivated, and wherein the passivated portion of the first doped semiconductor layer substantially insulates the first electrode from the edges of the first doped semiconductor layer, thereby reducing surface recombination. The device further includes a second electrode coupled to the second doped semiconductor layer and a passivation layer which substantially covers the sidewalls of the first and second doped semiconductor layers, the MQW active layer, and part of the horizontal surface of the second doped semiconductor layer which is not covered by the second electrode.

In a variation on this embodiment, the substrate comprises at least one of the following materials: Cu, Cr, Si, and SiC.

In a variation on this embodiment, the passivation layer comprises at least one of the following materials: SiOₓ, SiNₓ, and SiOₓN_{y}.

In a variation on this embodiment, the first doped semiconductor layer is a p-type doped semiconductor layer.

In a further variation on this embodiment, the passivated portion of the p-type doped semiconductor layer is not covered by Pt and is formed by a selective low-temperature annealing process which precludes the dopants in the passivated portion from being activated.

In a further variation on this embodiment, the passivated portion of the p-type doped semiconductor layer is formed by a selective passivation process which introduces hydrogen ions to the passivated portion.

In a variation on this embodiment, the second doped semiconductor layer is an n-type doped semiconductor layer.

In a variation on this embodiment, the MQW active layer comprises GaN and InGaN.

In a variation on this embodiment, the passivation layer is formed by one of the following processes: plasma-enhanced chemical vapor deposition (PECVD), magnetron sputtering deposition, and electron beam (e-beam) evaporation.

In a variation on this embodiment, the thickness of the passivation layer is between 300 Å and 10,000 Å.

### BRIEF DESCRIPTION OF THE FIGURES

FIG. 1 illustrates a traditional passivation method for an LED with a vertical-electrode configuration.

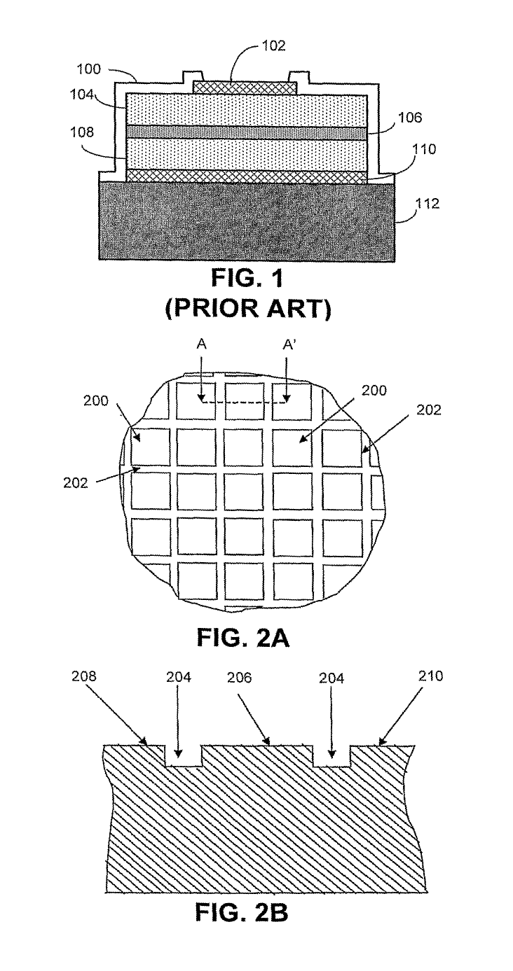

FIG. 2A illustrates part of a substrate with pre-patterned grooves and mesas in accordance with one embodiment of the present invention.

FIG. 2B illustrates the cross section of a pre-patterned substrate in accordance with one embodiment of the present invention.

FIG. 3 presents a diagram illustrating the process of fabricating a light-emitting device with passivation in the p-type layer in accordance with one embodiment of the present invention.

FIG. 4 presents a diagram illustrating the process of fabricating a light-emitting device with passivation in the p-type layer in accordance with one embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Overview

Embodiments of the present invention provide a method for fabricating an LED device with passivation inside the p-type layer. The combination of a passivated portion inside the p-type layer and a separate passivation layer can effectively reduce surface recombination of the carriers, resulting in improved reliability of the LED device. In one embodiment of the present invention, instead of depositing only a single passivation layer at the outer surface of a multilayer semiconductor structure (which includes an n-typed doped layer, a p-type doped layer, and an active layer), a passivated portion is also formed inside the p-type layer. The presence of the passivated portion inside the p-type layer provides substantial insulation between the sidewalls of the p-n junction and the p-side electrode, thereby reducing the leakage current.

### Preparing the Substrate

InGaAlN (InₓGa_{y}Al_{1-x-y}N, 0<=x<=1, 0<=y<=1) is one of the optimal materials for manufacturing short-wavelength light-emitting devices. In order to grow a crack-free multilayer InGaAlN structure on a conventional large-area substrate (such as a Si wafer), a growth method that pre-patterns the substrate with grooves and mesas is introduced. Pre-patterning the substrate with grooves and mesas can effectively release the stress in the multilayer structure that is caused by lattice-constant and thermal-expansion-coefficient mismatches between the substrate surface and the multilayer structure.

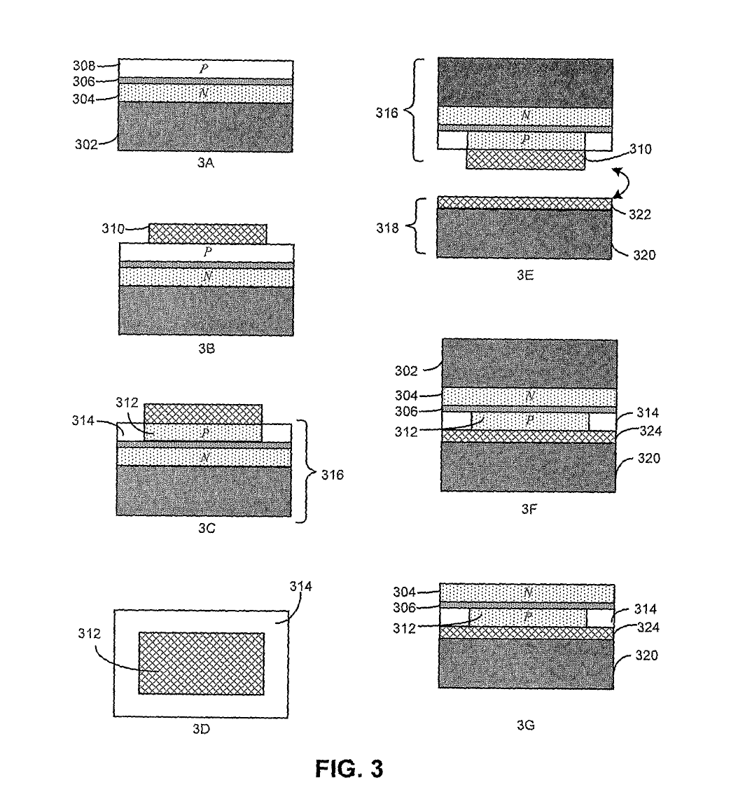

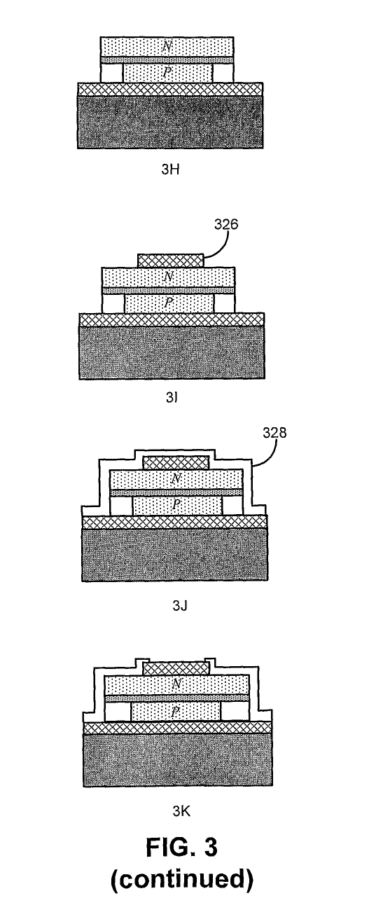

FIG. 2A illustrates a top view of a part of a substrate with a pre-etched pattern using photolithographic and plasma-etching techniques in accordance with one embodiment of the present invention. Square mesas 200 and grooves 202 are the result of the etching. FIG. 2B more clearly illustrates the structure of mesas and grooves by showing a cross section of the pre-patterned substrate along a horizontal line AA′ in FIG. 2A in accordance with one embodiment of the present invention. As seen in FIG. 2B, the sidewalls of grooves 204 effectively form the sidewalls of the isolated mesa structures, such as mesa 206, and partial mesas 208 and 210. Each mesa defines an independent surface area for growing a respective semiconductor device.

Note that it is possible to apply different lithographic and etching techniques to form the grooves and mesas on the semiconductor substrate. Also note that other than forming square mesas 200 as shown in FIG. 2A, alternative geometries can be formed by changing the patterns of grooves 202. Some of these alternative geometries can include, but are not limited to: triangular, rectangular, parallelogram, hexagon, circular, or other non-regular shapes.

### Passivation in P-Type Layer by Selective Annealing

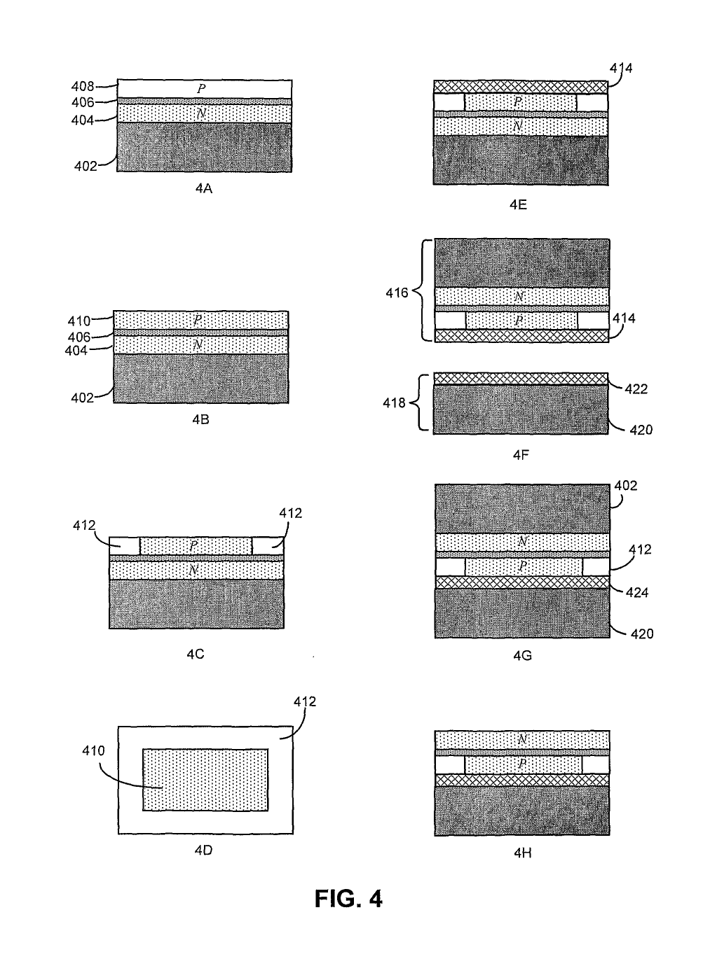

FIG. 3 presents a diagram illustrating the process of fabricating a light-emitting device with passivation in the p-type layer in accordance with one embodiment of the present invention. In operation 3A, after a pre-patterned substrate with grooves and mesas is prepared, an InGaAlN multilayer structure can be formed using various growth techniques, which can include but are not limited to metalorganic-chemical-vapor-deposition (MOCVD). The multilayer structure can include a substrate 302, which can be a Si wafer; an n-type doped semiconductor layer 304, which can be a Si doped GaN layer; an active layer 306, which can be a multi-period GaN/InGaN MQW structure; and a p-type doped semiconductor layer 308, which can be a Mg doped GaN layer. It is possible to reverse the sequence of the growth between the p-type layer and n-type layer. Note that the MOCVD grown p-type layer 308, which can be a Mg doped GaN layer, usually shows semi-insulating properties. Therefore, a thermal annealing process is used to activate the p-type dopant (the Mg ions).

In operation 3B, a thin metal layer 310 is formed on top of the p-type doped semiconductor layer covering the center portion of the p-type layer. Metal layer 310 may include several types of metal, such as nickel (Ni), gold (Au), platinum (Pt), and an alloy thereof. In one embodiment of the present invention, thin metal layer 310 includes a layer of Pt, which is in contact with the p-type layer. The presence of Pt makes it possible to activate the p-type dopant using a low temperature thermal annealing process. Metal layer 310 can be deposited using an evaporation technique such as electro-beam (e-beam) evaporation.

In operation 3C, low-temperature thermal annealing is performed to the multi-layer structure 316. As a result, the acceptors in a portion of p-type layer 308 that is covered by thin metal layer 310 are activated, forming a substantially conductive p-type region 312. On the other hand, the acceptors in the portion of p-type doped layer 308 that is not covered by thin metal layer 310 remain un-activated, forming a substantially insulating (or passivation) region 314. Illustration 3D shows the top view of the multilayer structure after the low-temperature annealing process.

In operation 3E, multilayer structure 316 is flipped upside down to bond with a supporting conductive structure 318. Note that, in one embodiment, supporting conductive structure 318 includes a supporting substrate 320 and a bonding layer 322. In addition, a layer of bonding metal can be deposited on metal layer 310 to facilitate the bonding process. Supporting substrate layer 320 is conductive and may include silicon (Si), copper (Cu), silicon carbide (SiC), chromium (Cr), and other materials. Bonding layer 322 may include gold (Au). Illustration 3F shows the multilayer structure after bonding. Note that, after bonding, metal layer 310 and bonding layer 322 bond together to form a p-side electrode 324.

In operation 3G, substrate 302 is removed. Techniques that can be used for the removal of the substrate layer 302 can include, but are not limited to: mechanical grinding, dry etching, chemical etching, and any combination of the above methods. In one embodiment, the removal of substrate 302 is completed by employing a chemical-etching process, which involves submerging the multilayer structure in a solution based on hydrofluoric acid, nitric acid, and acetic acid. Note that supporting substrate layer 320 can be optionally protected from this chemical etching.

In operation 3H, the edge of the multilayer structure is removed to reduce surface recombination centers and to ensure high material quality throughout the entire device. However, if the growth procedure can guarantee a good edge quality of the multilayer structure, then this edge removal operation can be optional.

In operation 3I, after the edge removal, n-side electrode 326 is formed on top of the multilayer structure. The metal composition and the formation process of the n-side electrode can be similar to that of metal layer 310.

In operation 3J, a top passivation layer 328 is deposited. Materials that can be used to form the top passivation layer include, but are not limited to, the following: SiOₓ, SiNₓ, and SiOₓN_{y}. Various thin-film deposition techniques, such as PECVD and magnetron sputtering deposition, can be used to deposit the top passivation layer. The thickness of the top passivation layer can be between 300 and 10,000 angstroms. In one embodiment of the present invention, the top passivation layer has a thickness of approximately 2,000 angstroms.

In operation 3K, photolithographic patterning and etching are applied to top passivation layer 328 to expose the n-side electrode.

### Passivation in P-Type Layer by Selective Passivation

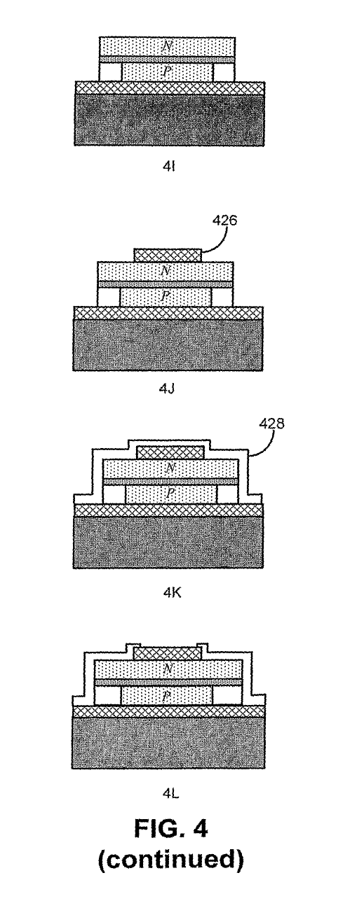

FIG. 4 presents a diagram illustrating the process of fabricating a light-emitting device with passivation in the p-type layer in accordance with one embodiment of the present invention. Operation 4A is similar to operation 3A, which results in an InGaAlN multilayer semiconductor structure that includes a substrate 402, an n-type doped semiconductor layer 404, an active layer 406, and a p-type doped semiconductor layer 408.

In operation 4B, the multilayer structure undergoes a high temperature thermal annealing process. As a result, the p-type dopant, or the acceptors, inside p-type layer 408 are activated. As a result, a substantially conductive p-type layer 410 is formed.

In operation 4C, conductive p-type layer 410 is selectively passivated in certain regions, such as passivated regions 412. The selective passivation process can be performed by first protecting the center portion of the p-type layer with a mask, and then exposing the multilayer structure to H₂ or NH₃ plasma. The H ions can effectively passivate the unprotected regions of p-type layer 410, resulting in substantially insulating regions 412. After the passivation process, the mask is removed. Illustration 4D shows the top view of the multilayer structure after the selective passivation process.

In operation 4E, a metal layer 414 is deposited on top of p-type layer 410. Metal layer 414 may include several types of metal such as Ni, Au, Pt, and an alloy thereof. Metal layer 414 can be deposited using an evaporation technique such as electro-beam (e-beam) evaporation.

In operation 4F, multilayer structure 416 is flipped upside down to bond with a supporting conductive structure 418. Note that, in one embodiment, supporting conductive structure 418 includes a supporting substrate 420 and a bonding layer 422. In addition, a layer of bonding metal can be deposited on metal layer 414 to facilitate the bonding process. Supporting substrate layer 420 is conductive and may include silicon (Si), copper (Cu), silicon carbide (SiC), chromium (Cr), and other materials. Bonding layer 422 may include Au. Illustration 4G shows the multilayer structure after bonding. Note that, after bonding, metal layer 414 and bonding layer 422 bond together to form a p-side electrode 424.

In operation 4H, substrate 402 is removed. Techniques that can be used for the removal of the substrate layer 402 can include, but are not limited to: mechanical grinding, dry etching, chemical etching, and any combination of the above methods. In one embodiment, the removal of substrate 402 is completed by employing a chemical-etching process, which involves submerging the multilayer structure in a solution based on hydrofluoric acid, nitric acid, and acetic acid. Note that supporting substrate layer 420 can be optionally protected from this chemical etching.

In operation 4I, the edge of the multilayer structure is removed to reduce surface recombination centers and to ensure high material quality throughout the entire device. However, if the growth procedure can guarantee a good edge quality of the multilayer structure, then this edge removal operation can be optional.

In operation 4J, after the edge removal, n-side electrode 426 is formed on top of the multilayer structure. The metal composition and the forming process of the n-side electrode can be similar to that of metal layer 414.

In operation 4K, a top passivation layer 428 is deposited. Materials that can be used to form the top passivation layer include, but are not limited to: SiOₓ, SiNₓ, and SiOₓN_{y}. Various thin-film deposition techniques, such as PECVD and magnetron sputtering deposition, can be used to deposit the top passivation layer. The thickness of the top passivation layer can be between 300 and 10,000 angstroms. In one embodiment of the present invention, the top passivation layer has a thickness of approximately 2,000 angstroms.

In operation 4L, photolithographic patterning and etching are applied to top passivation layer 428 to expose n-side electrode 426.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the various embodiments is defined by the appended claims.

What is claimed is:

1. A semiconductor light-emitting device, comprising:
a substrate;
a first doped semiconductor layer situated above the substrate;
a second doped semiconductor layer situated above the first doped semiconductor layer;
a multi-quantum-well (MQW) active layer situated between the first and the second doped semiconductor layers;
a first electrode coupled to the first doped semiconductor layer;
wherein part of the first doped semiconductor layer is passivated, and wherein the passivated portion of the first doped semiconductor layer substantially insulates the first electrode from the edges of the first doped semiconductor layer, thereby reducing surface recombination;
a second electrode coupled to the second doped semiconductor layer; and
a passivation layer which substantially covers the sidewalls of the first and second doped semiconductor layers, the MQW active layer, and part of the horizontal surface of the second doped semiconductor layer which is not covered by the second electrode.

2. The semiconductor light-emitting device of claim 1,
wherein the substrate comprises at least one of the following materials:
Cu,
Cr,
Si, and
SiC.

3. The semiconductor light-emitting device of claim 1,
wherein the passivation layer comprises at least one of the following materials:
silicon oxide (SiOₓ),
silicon nitride (SiNₓ,), and
silicon oxynitride (SiOₓN_{y}).

4. The semiconductor light-emitting device of claim 1,
wherein the first doped semiconductor layer is a p-type doped semiconductor layer.

5. The semiconductor light-emitting device of claim 4,
wherein the passivated portion of the p-type doped semiconductor layer is not covered by Pt and is formed by a selective low-temperature annealing process which precludes the dopants in the passivated portion from being activated.

6. The semiconductor light-emitting device of claim 4,
wherein the passivated portion of the p-type doped semiconductor layer is formed by a selective passivation process which introduces hydrogen ions to the passivated portion.

7. The semiconductor light-emitting device of claim 1,
wherein the second doped semiconductor layer is an n-type doped semiconductor layer.

8. The semiconductor light-emitting device of claim 1,
wherein the MQW active layer comprises GaN and InGaN.

9. The semiconductor light-emitting device of claim 1,
wherein the passivation layer is formed by at least one of the following processes:
plasma-enhanced chemical vapor deposition (PECVD),
magnetron sputtering deposition, or
electro-beam (e-beam) evaporation.

10. The semiconductor light-emitting device of claim 1,
wherein the thickness of the passivation layer is between 300 and 10,000 angstroms.

11. A method for fabricating a semiconductor light-emitting device, the method comprising:
fabricating a multilayer semiconductor structure on a first substrate, wherein the multilayer semiconductor structure comprises a first doped semiconductor layer, an MQW active layer, and a second doped semiconductor layer;
forming a passivated portion in the first doped semiconductor layer, thereby substantially insulating the edges of the first doped semiconductor layer from a subsequently formed first electrode;
forming the first electrode, which is coupled to the first doped semiconductor layer;
bonding the multilayer structure to a second substrate;
removing the first substrate;
forming a second electrode, which is coupled to the second doped semiconductor layer; and
forming a passivation layer, which substantially covers the sidewalls of the first and second doped semiconductor layers, the MQW active layer, and part of the surface of the second doped semiconductor layer which is not covered by the second electrode.

12. The method of claim 11,
wherein the substrate comprises at least one of the following materials:
Cu,
Cr,
Si, and
SiC.

13. The method of claim 11,
wherein the passivation layer comprises at least one of the following materials:
silicon oxide (SiOₓ),
silicon nitride (SiNₓ), and
silicon oxynitride (SiOₓN_{y}).

14. The method of claim 11,
wherein the first doped semiconductor layer is a p-type doped semiconductor layer.

15. The method of claim 14,
wherein forming a passivated portion in the p-type doped semiconductor layer comprises selectively activating the p-type dopant in the un-passivated portions by introducing Pt to the un-passivated portions during a low-temperature annealing process.

16. The method of claim 14,
wherein forming a passivated portion in the p-type doped semiconductor layer comprises first activating the dopants in the entire p-type layer and then selectively passivating a portion of the p-type layer by introducing hydrogen ions to the passivated portion.

17. The method of claim 11,
wherein the second doped semiconductor layer is an n-type doped semiconductor layer.

18. The method of claim 11,
wherein the MQW active layer comprises GaN and InGaN.

19. The method of claim 11,
wherein the first substrate comprises a pre-defined pattern of grooves and mesas.

20. The method of claim 11,
wherein the passivation layer is formed by one of the following processes:
plasma-enhanced chemical vapor deposition (PECVD),
magnetron sputtering deposition, and
e-beam deposition.

21. The method of claim 11,
wherein the thickness of the passivation layer is between 300 Å and 10,000 Å.
